(19) United States
(12) Patent Application Publication
(10) Pub. No.: US 2005/0054178 A1
(43) Pub. Date: Mar. 10, 2005

(54) Electric device, its manufacturing method, and electronic equipment

(75) Inventor: Sumio Utsunomiya, Suwa-shi (JP)

Correspondence Address: BANNER & WITCOFF, 1001 G STREET N W, SUITE 1100, WASHINGTON, DC, 20001, US

(73) Assignee: Seiko Epson Corporation, Shinjuku-ku (JP)

(21) Appl. No.: 10/936,826

(22) Filed: Sep. 9, 2004

(30) Foreign Application Priority Data
Sep. 10, 2003 (JP) 2003-318962(P)

(51) Int. Cl. H01L 21/00; H01L 27/15; H01L 31/12; H01L 29/267; H01J 63/04; H01J 1/62; H01L 23/02

(52) U.S. Cl. 438/458; 438/26; 257/678; 257/81

(57) ABSTRACT

A technique enabling a reduction in manufacturing cost of an electric device (for example, an organic EL display device) using a substrate requiring a barrier layer is described. A manufacturing method of the electric device of may include forming a peeling layer on a first substrate, forming a transferred layer that includes an electric element on the peeling layer, forming the barrier layer on the transferred layer, bonding a second substrate to the transferred layer formation on a surface side of the first substrate via an adhesive layer, transferring energy to the peeling layer through the first substrate to cause peeling in the peeling layer, and separation of the first substrate from the second substrate.

### RELATED APPLICATION INFORMATION

This application claims priority to Japanese Patent Application No. 2003-318962, filed Sep. 10, 2003, whose contents are expressly incorporated herein by reference.

### FIELD OF THE INVENTION

Aspects of the present invention relate to semiconductor manufacturing techniques. More particularly, aspects of the present invention relate to a manufacturing technique for an electric device such as an organic EL display device.

### BACKGROUND

Organic EL (electro-luminescence) display devices have attracted attention as thin, lightweight display devices capable of displaying high-quality images. The structure of a general organic EL display device includes an illuminating organic EL element, a drive circuit for driving the organic EL element, and formed on a glass substrate. Recently, so as to make the organic EL display device more lightweight, stronger or more flexible, the use of a plastic substrate instead of a conventional glass substrate has been considered.

The organic EL element is extremely vulnerable to intrusion of moisture, oxygen and the like. The organic EL element easily deteriorates because of exposure to these adverse substances. Glass substrates act as a barrier to prevent intrusion of adverse substances. While having the benefits described above, the plastic substrate as compared with the glass substrate, however, tends be inferior in barrier performance with respect to the intrusion of adverse substances such as moisture (moisture vapor), oxygen and hydrogen. Therefore, where the plastic substrate is used, a barrier layer is applied for preventing (or suppressing) the intrusion of adverse substances through the plastic substrate between the organic EL element and the plastic substrate. An example of an organic EL display device having such a barrier layer is described in documents such as Japanese Laid Open Patent Publication No. 2003-109748, for example. The barrier layer may include, for example, an inorganic film such as a silicon dioxide film and a silicon nitride film, or a composite film in which such an inorganic film and an organic film are deposited alternately in several layers.

Forming a barrier layer on the plastic substrate by current techniques is not cost-effective. When the plastic substrate is used as a component of the organic EL display device, the formation of the barrier layer costs can be excessive and thus manufacturing costs of the organic EL display device increase. Furthermore, increased manufacturing costs similarly occur when manufacturing an electronic device using a substrate (plastic or any other kind) requiring a barrier layer for avoiding intrusion of adverse substances.

### SUMMARY

Aspects of the present invention overcome one or more of the issues described above, thereby providing a technique enabling a reduction in manufacturing costs of an electric device using a substrate with a barrier layer. These and other aspects are described with respect to the drawings.

### BRIEF DESCRIPTION OF THE DRAWINGS

FIG. 1 is a view for explaining a structure of an organic EL display device of a first illustrative embodiment (cross-sectional view) of the present invention.

FIGS. 2A-2D are views for explaining a manufacturing method of the organic EL display device of the first illustrative embodiment of the present invention.

FIGS. 3A-3C are views for explaining the manufacturing method of the organic EL display device of the first illustrative embodiment of the present invention.

FIGS. 4A-4C are views for explaining the manufacturing method of the organic EL display device of the first illustrative embodiment of the present invention.

FIG. 5 is a view for explaining a structure of an organic EL display device of a second illustrative embodiment (cross-sectional view) of the present invention.

FIGS. 6A-6C are views for explaining a manufacturing method of the organic EL display device of the second illustrative embodiment of the present invention.

FIGS. 7A-7C are views for explaining the manufacturing method of the organic EL display device of the second illustrative embodiment of the present invention.

FIGS. 8A-8C are views for explaining the manufacturing method of the organic EL display device of the second illustrative embodiment of the present invention.

FIGS. 9A-9C are views for explaining the manufacturing method of the organic EL display device of the second illustrative embodiment of the present invention.

FIGS. 10A-10C are views for explaining a manufacturing method of an organic EL display device of a third illustrative embodiment of the present invention.

FIGS. 11A-11F are views showing examples of electronic equipment to which an electro-optic device according to aspects of the present invention can be applied.

FIGS. 12A-12B are views showing additional examples of electronic equipment to which an electro-optic device according to aspects of the present invention can be applied.

### DETAILED DESCRIPTION

Aspects of the present invention include a transfer technique in which a transferred layer that includes an electric element or the like is formed in advance on a substrate, where the substrate serves as a transfer source via a peeling layer. The transferred layer may be bonded to a transfer substrate. Light or the like may be projected to the peeling layer to cause peeling, thereby transferring the transferred layer to the transfer substrate. Detailed contents of the transfer technique are described in documents such as Japanese Laid Open Patent Publication No. HI 1-74533, for example, whose contents are expressly incorporated herein by reference (corresponding to U.S. Pat. No. 6,372,608).

It is noted that various connections are set forth between elements in the following description. It is noted that these connections in general and, unless specified otherwise, may be direct or indirect and that this specification is not intended to be limiting in this respect.

Terms

The following provides a glossary of terms used in the following description of the invention.

| | |
|---|---|
| Electric | The electric element may include, for example, an electro- |
| element: | optic element such as an organic EL element and an |
| | electrophoretic element, a thin film semiconductor element |
| | such as a thin film transistor and a thin film diode, a |
| | photoelectric conversion element used for a solar battery, |
| | an image sensor or the like, a switching element, a memory |
| | cell, or the like. |
| Electric | The electric device may include various electric elements, |
| device: | a thin film circuit comprising the electric element, or the |
| | like as formed on a substrate. The electric device may |
| | include, for example, an electro-optic device such as an |
| | organic EL display device including the organic EL element |
| | and the thin film semiconductor element/circuit driving the |
| | organic EL element as described above. |
| Electro- | An electro-optic device denotes a general display device |
| optic | that includes an electro-optic element that emits light by |
| device: | electric action or changes a light state from the outside. |
| | This definition encompasses devices that emit light |
| | themselves and/or control the transmission of the light from |
| | outside the devices. |
| Adverse | Adverse substances include substances having adverse |
| substances: | effects (for instance, causing deterioration) on an |
| | electric device. Adverse substances include, but are not |
| | limited to, water, oxygen, hydrogen and the like. The |
| | barrier layer tends to prevent intrusion of these adverse |
| | substances to the device layer through a substrate. |
| | Adverse substances may include substances that are |
| | intrinsic and/or extrinsic to the circuit. |
| Electronic | Electronic equipment relates to general equipment |
| equipment: | comprising the above-mentioned electric device or |
| | other elements exerting a predetermined function, while not |
| | being limited in structure. Electronic equipment, for |
| | example, may include an IC card, cellular phone, video |
| | camera, personal computer, head-mounted display, |
| | rear-type or front-type projector, and other devices |
| | (including but not limited to a fax device with display |
| | function, a finder of a digital camera, a portable television, |
| | a DSP device, a PDA, an electronic data book, an |
| | electric bulletin board, and a commercial display). |

General Aspects of the Invention

The following describes general aspects of the invention.

A manufacturing method for manufacturing an electric device according to of a first aspect of the present invention comprises: a first step of forming a peeling layer on a first substrate (transfer source substrate); a second step of forming a transferred layer (device layer) on the peeling layer where the transferred layer includes an electric element,; a third step of forming a barrier layer suppressing intrusion of adverse substances on the transferred layer; a fourth step of bonding a second substrate (transfer substrate) to the transferred layer formation surface side of the first substrate via an adhesive layer; and a fifth step of transferring energy to the peeling layer through the first substrate to cause peeling in the peeling layer, and separating the first substrate from the second substrate.

According to such a method, even when a plastic substrate or the like (on which it is not easy to form the barrier layer) is used as the second substrate, the barrier layer does not need to be formed directly on the second substrate. As a result, the electric device using such a substrate (e.g., the plastic substrate) may be manufactured at lower cost. Furthermore, since materials that are more suitable for manufacturing the barrier layer or the transferred layer can be used, a broad range of choices for process conditions, materials, or the like exists for forming the first substrate as compared with a case where the barrier layer is formed directly on the second substrate. Accordingly, conditions that can further reduce the manufacturing cost can be chosen to form the barrier layer. In addition, the electric device can be manufactured at lower cost using a substrate such as the plastic substrate.

One may optionally include a “sixth step of forming a protective layer interposed between the peeling layer and the transferred layer, prior to the second step. One advantage of using this optional step is that the protective layer protects an upper surface of the device layer transferred to the second substrate (where the second substrate has also been formed on the first substrate) while being easy to manufacture. In addition to the protective layer, a barrier layer similar to the above-mentioned barrier layer may be formed.

A manufacturing method of an electric device according to the second aspect of the present invention, comprises: a first step of forming a first peeling layer on a first substrate (transfer source substrate); a second step of forming a barrier layer suppressing intrusion of adverse substances on the first peeling layer; a third step of forming a transferred layer that includes an electric element, on the barrier layer; a fourth step of preparing a temporary transferring substrate for temporarily supporting the barrier layer and the transferred layer, and forming a second peeling layer on one surface of the temporary transferring substrate; a fifth step of interposing an interim adhesive layer capable of being removed later between the transferred layer formation surface side of the first substrate and the second peeling layer formation surface side of the temporary transferring substrate, and bonding the first substrate and the temporary transferring substrate; a sixth step of transferring energy to the first peeling layer through the first substrate to cause peeling in the first peeling layer, and separating the first substrate from the temporary transferring substrate; a seven step of bonding a second substrate (transfer substrate) to the barrier layer formed on the transferred layer via an adhesive layer; and an eighth step of transferring energy to the second peeling layer through the temporary transferring substrate to cause peeling in the second peeling layer, and separating the temporary transferring substrate from the second substrate.

According to such a method, as with the method of the first aspect of the invention, the barrier layer does not need to be formed directly on the second substrate. The formation of the barrier layer (on the first substrate) provides a simplified manufacturing technique, so that the electric device using such a substrate as the plastic substrate can be manufactured at lower cost.

Optionally, a ninth step may be included that removes the interim adhesive layer after the above-mentioned eighth step. Thereby, where the interim adhesive layer is not necessary after the transferred layer is transferred, the interim adhesive layer may be removed.

Further, a tenth step of forming a protective layer on the transferred layer after the above-mentioned ninth step may be optionally performed. This protective layer may be formed similar to the barrier layer described above.

Further, the above-mentioned protective layer may be formed on the first substrate. The method may further include an eleventh step of forming a protecting layer on the transferred layer after the third step. One benefit is that the protective layer protects an upper surface of the device layer. Also, the protective layer may be readily manufactured on the first substrate.

A manufacturing method of an electric device of a third aspect of the present invention comprises: a first step of forming a peeling layer on a first substrate; a second step of forming a barrier layer suppressing intrusion of adverse substances on the peeling layer; a third step of forming a transferred layer that includes an electric element, temporarily on the barrier layer; a fourth step of preparing a temporary transferring substrate for temporarily supporting the barrier layer and the transferred layer, and interposing an interim adhesive layer capable of being removed later between one surface of the temporary transferring substrate and the transferred layer formation surface side of the first substrate, and bonding the first substrate and the temporary transferring substrate; a fifth step of transferring energy to the peeling layer through the first substrate to cause peeling in the peeling layer, and separating the first substrate from the temporary transferring substrate; a sixth step of bonding a second substrate to the barrier layer formed on the transferred layer via an adhesive layer; and a seventh step of removing the interim adhesive layer, and separating the temporary transferring substrate from the second substrate. The manufacturing method of the third aspect is similar to the above-mentioned manufacturing method according to the second aspect of the present invention. Differently, in the second transfer process, the temporary transferring substrate is separated by removing the interim adhesive layer without using the peeling layer.

According to such a method, as in the first or the second aspect of the present invention, the barrier layer does not need to be formed directly on the second substrate, and the formation of the barrier layer can easily be performed on the first substrate, so that the electric device using such a substrate as the plastic substrate can be manufactured at lower cost.

In the manufacturing method according to the third aspect of the present invention as well, one may optionally form a protective layer. As this protective layer, a barrier layer similar to the above-mentioned barrier layer may be formed.

An electric device of a fourth aspect of the present invention is formed by applying the above-mentioned manufacturing methods according to the present invention, and comprises the following structural feature. Specifically, the electric device according to the fourth aspect of the present invention comprises a substrate supporting respective components, an adhesive layer arranged on the substrate; a barrier layer arranged on the adhesive layer and suppressing intrusion of adverse substances, and a device layer including an electric element and arranged on the barrier layer.

According to a fifth aspect, the present invention has electronic equipment including the above-mentioned electric device.

### DESCRIPTION OF THE ILLUSTRATIVE EMBODIMENTS

Hereinafter, the illustrative embodiments of the present invention are described referring to the drawings. In the description below, as one example of an electric device according to the present invention, an organic EL display device is described.

### First Illustrative Embodiment

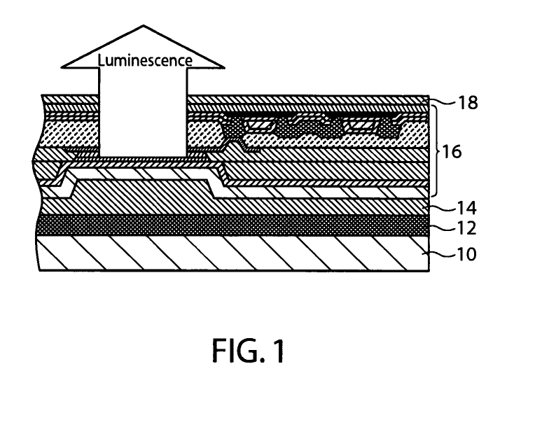

FIG. 1 is a view for explaining a structure of an organic EL display device of a first illustrative embodiment (cross-sectional view). The organic EL display device shown in FIG. 1 comprises a substrate 10 supporting an adhesive layer 12 arranged on this substrate 10, a barrier layer 14 arranged on the adhesive layer 12 and suppressing intrusion of adverse substances into a device layer 16, the device layer 16 comprising an organic EL element, a thin film transistor or the like and arranged on the barrier layer 14, and a protective layer 18 arranged on device layer 16. The organic EL display device of this example employs a so-called top emission type structure, in which light (luminescence) from the organic EL element is emitted away from substrate 10, as shown in FIG. 1.

In the present illustrative embodiment, a plastic substrate is used as the substrate 10. In the case where a thickness of the plastic substrate is 200 μm for example, a gas barrier performance of the plastic substrate is about 1.0 g/m²/per 24 hr with respect to moisture (H₂O), and about 10 cc/m²/per 24 hr with respect to oxygen (O₂). Thus, this performance is insufficient for the plastic substrate to be used for the organic EL display device. Therefore, the barrier layer 14 is used to suppress the intrusion of the adverse substances into the device layer 16 arranged on substrate 10. In the organic EL display device of the present illustrative embodiment, barrier layer 14 is not formed directly on the substrate 10, but the adhesive layer 12 is formed between both. Such a structural feature is obtained by applying, for example, a manufacturing method of the present illustrative embodiment described below.

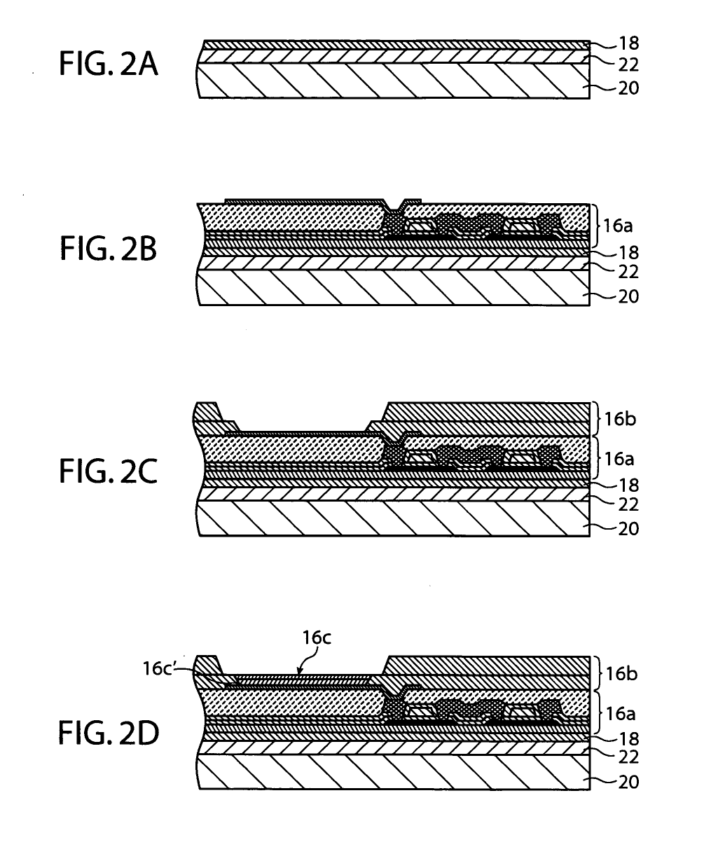

FIGS. 2A-2D, 3A-3C, and 4A-4C are views for explaining the manufacturing method of the organic EL display device of the first illustrative embodiments. The organic EL display device of the present illustrative embodiments is formed by employing a transfer technique in which the barrier layer 14, the device layer 16 or the like are formed on a substrate serving as a transfer source (a first substrate) that is then moved to the substrate 10 (a second substrate). Hereinafter, details are described.

As shown FIG. 2A, a peeling layer 22 is formed on a transfer source substrate 20 (the first substrate). Further, the protective layer 18 is formed on this peeling layer 22.

Here, the transfer source substrate 20 has an appropriate thickness and is made of a heat-resistant material such as quartz glass and soda glass, for example, one capable of withstanding about 350 through 1000° C. (which are process temperatures for manufacturing a semiconductor device). Furthermore, in order to enable energy to be transferred to the peeling layer by light irradiation in a later process, it is preferable for the transfer source substrate 20 to be transparent to a wavelength of the irradiated light.

The peeling layer 22 is a material that peels when irradiated with light because of energy transfer from the light to the peeling layer. Peeling layer 22 can be formed by, for example, a semiconductor film, a metal film, a conductive oxide film, conductive polymer film, conductive ceramics or the like. In the present illustrative embodiment, the peeling layer 22 is composed of an amorphous silicon film. The amorphous silicon film can be formed by, for example, a low pressure CVD method (LPCVD method) or a plasma CVD method (PECVD) using monosilan (SiH₄) or disilan (Si₂H₆) as a material gas. In these CVD processes, an appropriate amount of hydrogen (gas component) is contained in the amorphous silicon film.

The protective layer 18 protects device layer 16, as mentioned above, and various types thereof can be used as long as the function is carried out. In the present illustrative embodiment, with regard to this protective layer 18, one having a barrier function similar to the barrier layer 14 may also be used.

After the peeling layer 22 and the protective layer 18 are formed on the transfer source substrate 20 in this manner, the device layer 16 is formed on this protective layer 18. This device layer 16 is formed by depositing a thin film circuit layer 16a, an insulating layer 16b, an organic EL light-emitting layer 16c, and an electrode 16d, details of which are described later.

Specifically, as shown in FIG. 2B, there is formed the thin film circuit layer 16a including the thin film transistor, an electrode or the like which are used for driving the organic EL element. This thin film circuit layer 16a can be formed by employing well-known techniques.

Next, as shown in FIG. 2C, the insulating layer 16b is formed on an upper surface of the thin film circuit layer 16a. In this insulating layer 16b, a part corresponding to the electrode included in the thin film circuit layer 16a is opened. At this opened part, the organic EL light-emitting layer or the like is formed later. The insulating layer 16b may be composed of a polyimide film, for example.

Next, as shown in FIG. 2D, the organic EL light-emitting layer 16c is formed in the opening of the insulating layer 16b. In the illustrated example, a hole transporting layer 16c′ further interposed is shown between the organic EL light-emitting layer 16c and the electrode (of FIG. 2B). The organic EL light-emitting layer 16c and the hole transporting layer 16c′ can be formed using a droplet discharging method (ink jet method), for example. The hole transporting layer is formed using a mixture of polyethylene dioxithiophene and polystyrenesulfonic acid (PEDOT/PSS), for example. The organic EL light-emitting layer 16c is formed using a polydialkylfluorene derivative, for example.

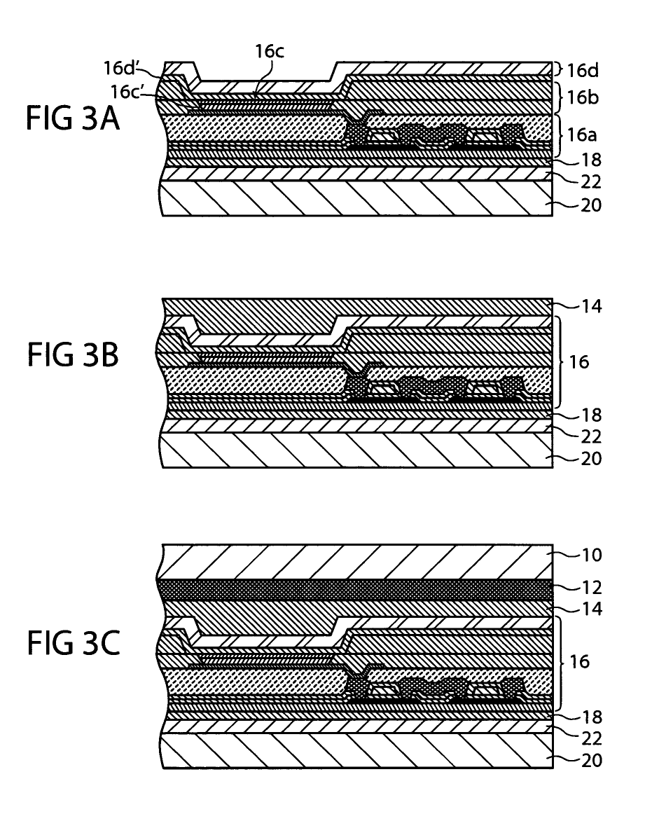

Next, as shown in FIG. 3A, the electrode 16d serving as a negative electrode of the organic EL element is formed above the insulating layer 16b. In the illustrated example, an electron transporting layer 16d′ is further interposed between electrode 16d and the organic EL light-emitting layer 16c. An aluminum film formed by a sputtering method for example can be used as electrode 16d. A film made of calcium, lithium, oxide of calcium or lithium, fluoride of the same, or the like can be used as the electron transporting layer 16d′.

By forming the device layer 16 in this manner, next, as shown in FIG. 3B, the barrier layer 14 is formed on the upper surface of the device layer 16. This barrier layer 14 takes on the function of suppressing the intrusion of adverse substances such as moisture, oxygen, and hydrogen into the device layer 16, as described above. As the barrier layer 14, various types can be employed as long as the function thereof can be achieved. For example, an inorganic film such as a silicon dioxide film and a silicon nitride film, or a composite film in which such an inorganic film and an organic film are deposited alternately in several layers can be used. As the composite film, for example, the multi-layered film such as (Al₂O₃/organic film) n, (SiON/organic film) n, (SiN/organic film) n or the like is preferably used.

Next, as shown in FIG. 3C, on the device layer 16 formation surface side of the transfer source substrate 20, the substrate 10 is bonded via the adhesive layer 12. By employing a transfer technique to transfer the circuit from substrate 20 to substrate 10, the substrate 10 does not need to have a heat resistance with respect to process temperatures at the semiconductor element manufacturing time, and thus the plastic substrate can be employed.

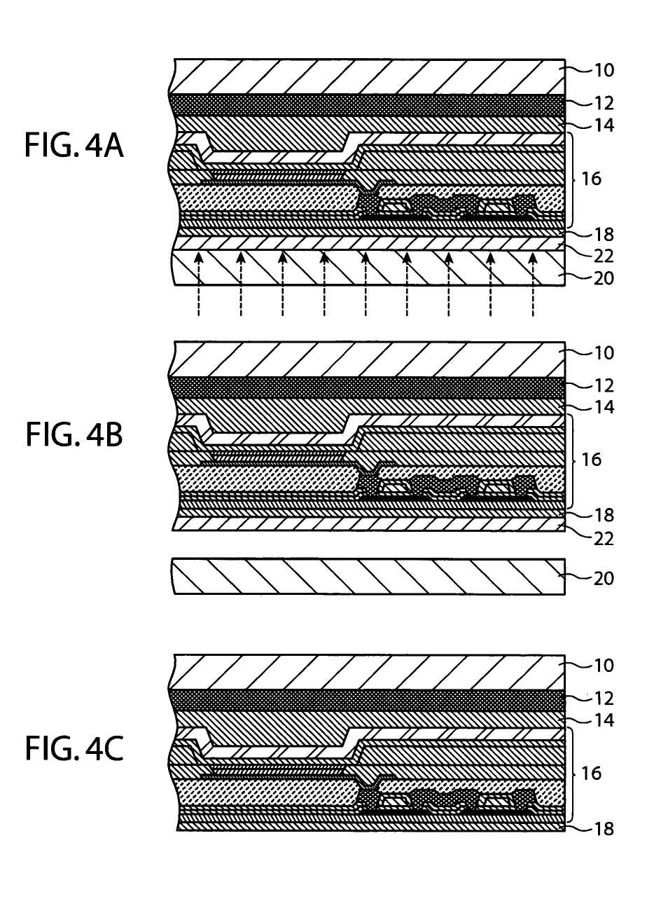

Next, as shown in FIG. 4A, energy is transferred by irradiating a laser beam to the peeling layer 22 through the transfer source substrate 20, and thereby generating laser ablation in the peeling layer 22. The ablation is a state in which a solid material (component material of the peeling layer 22) absorbing the irradiated light is excited photochemically or thermally, and the bonds of atoms or molecules on a surface and inside of the solid material are broken. Mainly, it appears as a phenomenon that the whole or a part of the component material of the peeling layer 22 undergoes phase change such as fusion and transpiration (vaporization). Furthermore, the phase change may bring about a fine foam state, thereby decreasing a bonding force. A laser beam having a wavelength of 308 nm and a pulse width of 20n seconds may be generated using an excimer laser, for example.

When peeling is caused in the peeling layer 22, as shown in FIG. 4B next, the transfer source substrate 20 is separated from the substrate 10. Thereafter, as necessary, the remaining peeling layer 22 is removed by such a method as etching. By way of the above steps, the organic EL display device of the present illustrative embodiment is completed as shown in FIG. 4C. The orientation of the view shown in FIG. 4C is upside down to that of the above-mentioned views shown in FIG. 1.

In this manner, according to the present illustrative embodiment, even in the case where the plastic substrate on which it is not easy to directly form the barrier layer 14 is used as the substrate 10 (the second substrate), which finally makes into a component of the organic EL display device, directly forming the barrier layer 14 on the substrate 10 is not necessary. This allows the organic EL display device using such a substrate as the plastic substrate with low barrier performance to be manufactured at lower cost. Furthermore, as the transfer source substrate 20 (the first substrate), one more suitable for the manufacturing of the barrier layer 14 and the device layer 16 (a transferred layer) can be used, and thus as compared with a case where the barrier layer 14 is formed directly on the substrate 10, a range of choices for process conditions, materials or the like is widened, thereby making it possible to choose conditions which can further reduce the manufacturing cost and form the barrier layer 14. From this point as well, the organic EL display device using such a substrate as the plastic substrate can be manufactured at lower cost.

### Second Illustrative Embodiment

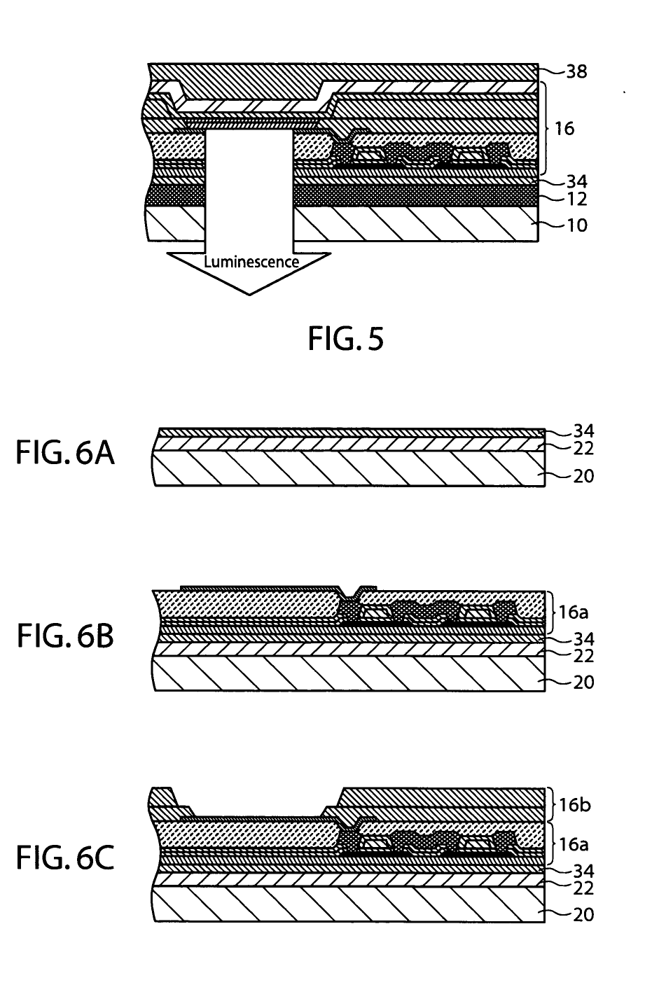

FIG. 5 is a view for explaining a structure of an organic EL display device of a second illustrative embodiment (cross-sectional view). The organic EL display device shown in FIG. 5 comprises the substrate 10 supporting respective components, the adhesive layer 12 arranged on this substrate 10, the barrier layer 34 arranged on the adhesive layer 12, and suppressing intrusion of adverse substances into the device layer, the device layer 16 including an organic EL element, a thin film transistor or the like and arranged on the barrier layer 34, and the protective layer 18 arranged on this device layer 16. The organic EL display device of this example employs a so-called bottom emission type structure, in which light (luminescence) from the organic EL element is emitted toward the substrate 10 side, as shown in the figure. Components similar to those of the above-mentioned organic EL display device of the first illustrative embodiment are indicated by the same reference numerals, and detailed description of these is omitted.

FIGS. 6A-6C, 7A-7C, 8A-8C, and 9A-9C are views for explaining a manufacturing method of the organic EL display device of the second illustrative embodiment. The organic EL display device of the present illustrative embodiment is formed by employing a transfer technique in which the barrier layer 14, the device layer 16 or the like are formed on a substrate serving as a transfer source (a first substrate), and after temporarily supporting this on a temporary transferring substrate, this is moved to the substrate 10 (a second substrate). Hereinafter, the details are described. Description of the contents overlapping with the first illustrative embodiment is omitted as necessary. 1611 As shown in FIG. 6A, the peeling layer 22 is formed on the transfer source substrate (the first substrate) 20. The barrier layer 34 is formed on peeling layer 22. Barrier layer 34 similar to the above-mentioned barrier layer 14 of the first illustrative embodiment is used.

Next, as shown in FIG. 6B, the thin film circuit layer 16a, as a component of the device layer 16, is formed on the barrier layer 34. Next, as shown in FIG. 6C, the insulating layer 16b is formed on the upper surface of the thin film circuit layer 16a. It is noted that the hole transport layer 16c′ and the electron transport layer 16d′ may or may not be used.

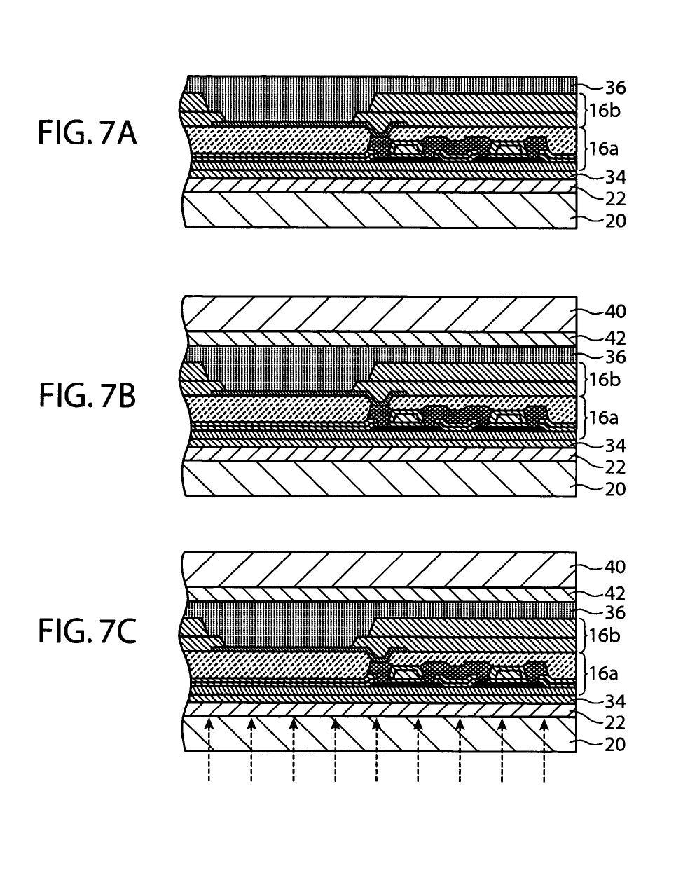

Next, as shown in FIG. 7A, an interim adhesive layer 36 is formed on the upper surface of the insulating layer 16b. This interim adhesive layer 36 is formed using a water-soluble adhesive material or the like which can be removed easily later. Furthermore, a temporary transferring substrate 40 for temporarily supporting the barrier layer 34 and the device layer 16 is prepared. A peeling layer 42 is formed on one surface of this temporary transferring substrate 40 (FIG. 7B). With regard to the peeling layer 42, one similar to the above-mentioned peeling layer 22 is used.

Next, as shown in FIG. 7B, between the device layer 16 formation surface side of the transfer source substrate 20 and the peeling layer 42 formation surface side of the temporary transferring substrate 40, the interim adhesive layer 36 is interposed, and the transfer source substrate 20 and the temporary transferring substrate 40 are bonded.

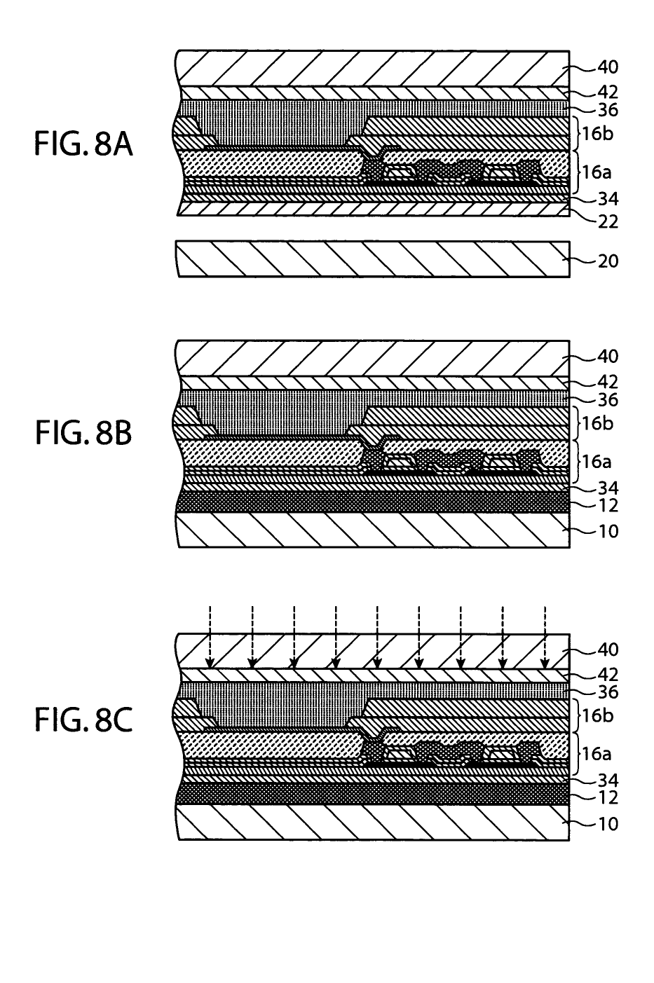

Next, as shown in FIG. 7C, a laser beam is irradiated to the peeling layer 22 through the transfer source substrate 20 to transfer energy, and to generate the laser ablation in the peeling layer 22. After peeling occurs in the peeling layer 22, the transfer source substrate 20 is separated from the temporary transferring substrate 40 as shown in FIG. 8A. Thereafter, the remaining peeling layer 22 is removed by such a method as etching as necessary.

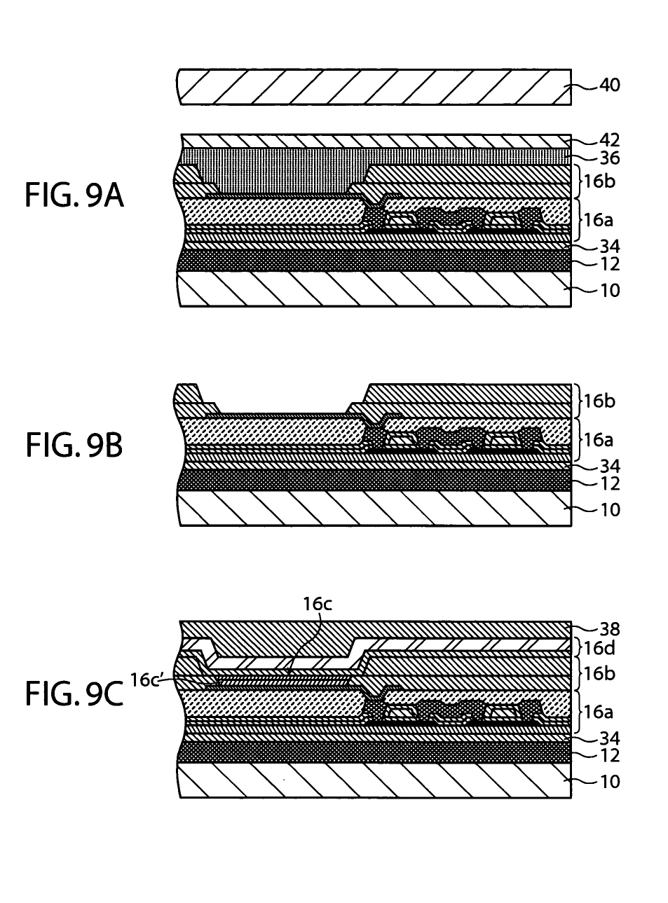

Next, as shown in FIG. 8B, the substrate 10 is bonded to the barrier layer 34 formed on the device layer 16 via the adhesive layer 12. Next, as shown in FIG. 8C, the laser beam is irradiated to the peeling layer 42 through the temporary transferring substrate 40 to transfer energy and to cause the peeling in the peeling layer 42, and as shown in FIG. 9A, the temporary transferring substrate 40 is separated from the substrate 10. Thereafter, the remaining peeling layer 42 is removed by such a method as etching or the like as necessary.

Next, as shown in FIG. 9B, the interim adhesive layer 36 is removed. Then, as shown in FIG. 9C, the organic EL light-emitting layer 16c, the electrode 16d, or the like are formed on the insulating layer 16b. A protective layer 38 is further formed on the upper surface of the electrode 16d. In the present illustrative embodiment one having the barrier function is used for this protective layer 38, as in the first illustrative embodiment.

In this manner, in the second illustrative embodiment, as in the first illustrative embodiment, since the barrier layer 34 does not need to be formed directly on the substrate 10, the barrier layer 34 can be formed on the transfer source substrate 20, and thus manufactured more easily, and an electric device using such a substrate as the plastic substrate can be manufactured at a lower cost.

In the above description, the thin film circuit layer 16a and the insulating layer 16b are first formed. These layers and the barrier layer 34 are transferred to the substrate 10, by way of the temporary transferring substrate. Next, the organic EL light-emitting layer 16c, the electrode 16d, and the protective layer 38 are formed. However, instead of performing these procedures, after the device layer 16 and the protective layer 38 have been formed on transfer source substrate 20, the transfer process can be performed prior to the formation of the layers.

### Third Illustrative Embodiment

A third illustrative embodiment is similar to the above-mentioned second illustrative embodiment. In the second transfer process of the third illustrative embodiment, the peeling layer 42 is not used, but the interim adhesive layer 36 is removed to thereby separate the temporary transferring substrate 40.

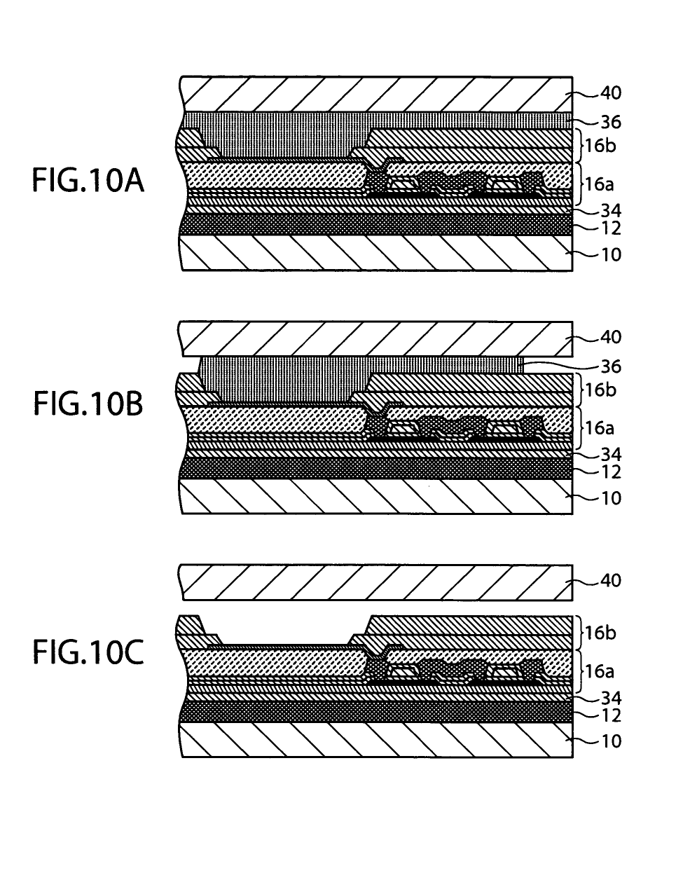

FIGS. 10A-C show a method for manufacturing an organic EL display device of the third illustrative embodiment. FIGS. 10A-C show cross sections after the peeling layer 22, the barrier layer 34, the thin film circuit layer 16a, and the insulating layer 16b have been formed (referring to FIGS. 6A through 6C) on the transfer source substrate 20 and the interim adhesive layer 36 has been formed on the upper surface of the insulating layer 16b (refer to FIG. 7A).

A temporary transferring substrate 40 is prepared in a similar manner to the step shown in FIG. 7B. Between the one surface of this temporary transferring substrate 40 and the upper surface of the transfer source substrate 20, the interim adhesive layer 36 is interposed, and the both substrates are bonded. In this third illustrative embodiment, the peeling layer 42 is not formed on the one surface of the temporary transferring substrate 40. Next, the transfer source substrate 20 is separated from the temporary transferring substrate 40 in a similar manner to the above-mentioned steps shown in FIGS. 7C and 8A. Thereafter, in a similar manner to the step shown in FIG. 8B, the substrate 10 is bonded to the barrier layer 34 formed on the device layer 16 via the adhesive layer 12 (see FIG. 10A).

Next, as shown in FIGS. 10B and 10C, the temporary transferring substrate 40 is separated from the substrate 10 by removing the interim adhesive layer 36. The organic EL display device similar to that shown in above-mentioned FIG. 5 is completed. 1741 In this manner, the third illustrative embodiment, as in the second illustrative embodiment, provides manufacturing efficiencies since the barrier layer 34 does not need to be formed directly on the substrate 10, the barrier layer 34 can be formed on the transfer source substrate 20 and thus manufactured more readily, and an electric device may use a substrate such as the plastic substrate or the like.

### Fourth Illustrative Embodiments

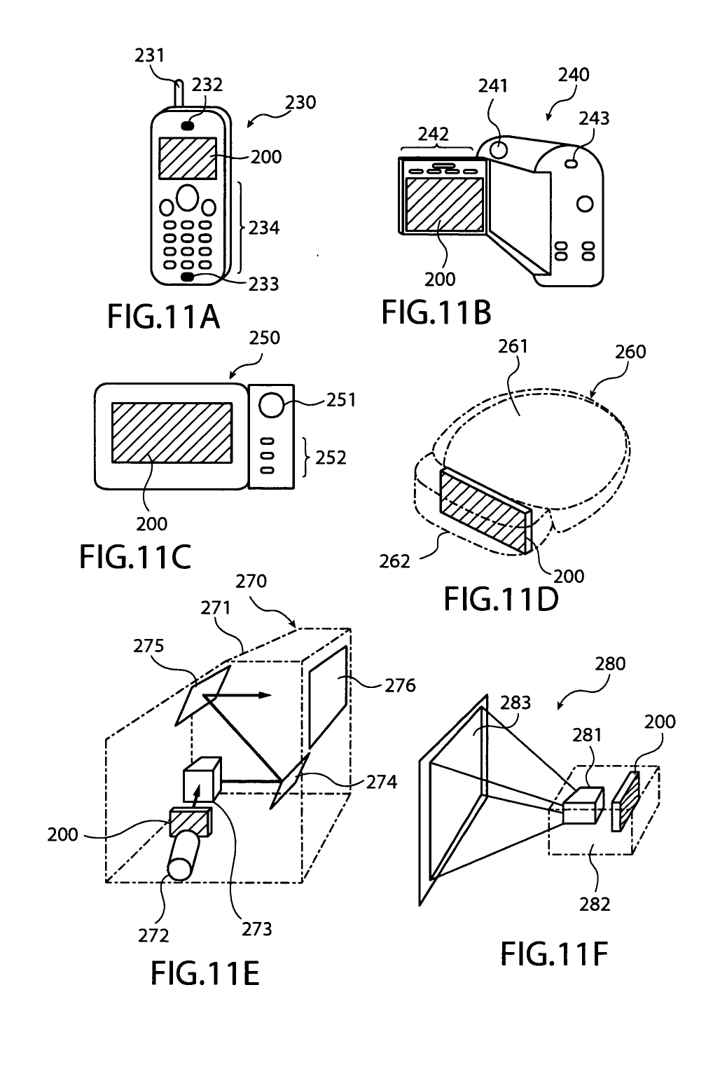

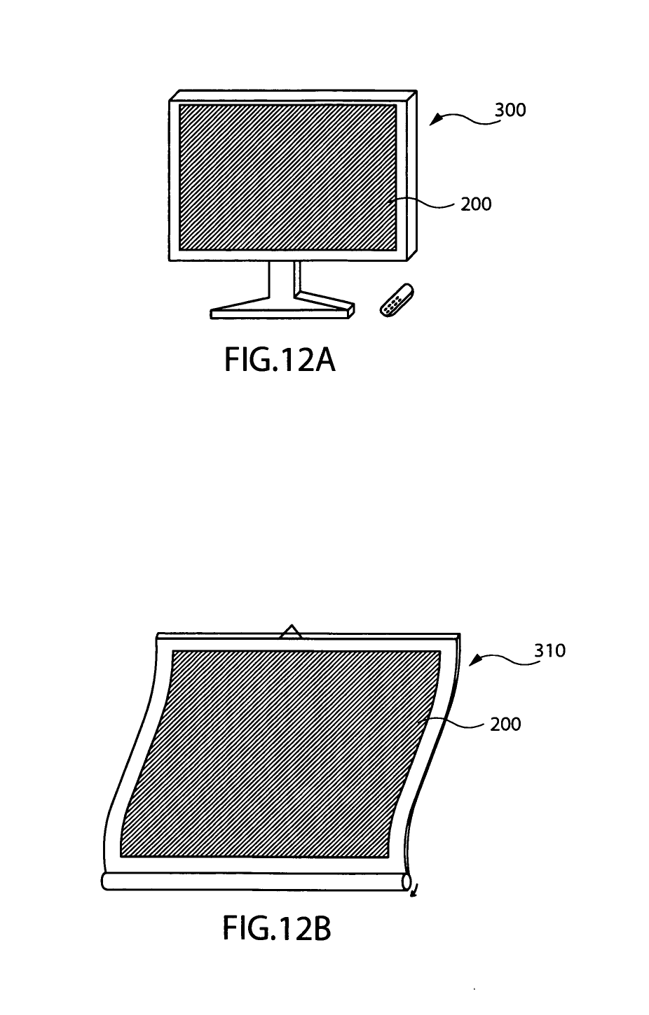

FIGS. 11A-11F and 12A-12B are views showing examples of electronic equipment to which the organic EL display devices according to the respective illustrative embodiments described above can be applied.

FIG. 11A shows an application example to a cellular phone. Cellular phone 230 comprises an antenna part 231, an audio output part 232, an audio input part 233, an operation part 234, and an electro-optic device 200 of the present invention. In this manner, the organic EL display device according to the present invention can be used as a display part.

FIG. 11B shows an application example to a video camera. Video camera 240 comprises an image receiving part 241, an operation part 242, an audio input part 243, and the organic EL display device 200 according to the present invention.

FIG. 11C shows an application example to a portable personal computer (so-called PDA). Computer 250 comprises a camera part 251, an operation part 252, and the organic EL display device 200 according to the present invention.

FIG. 11D shows an application example to a headed mount display. Headed mount display 260 comprises a band 261, an optical system storage part 262, and the organic EL display device 200 according to the present invention.

FIG. 11E shows an application example to a rear type projector. Projector 270 comprises a light source 272, a synthesis optical system 273, mirrors 274 and 275, a screen 276, and the organic EL display device 200 according to the present invention in a housing 271.

FIG. 11F shows an application example to a front type projector. Projector 280 comprises an optical system 281 and the organic EL display device 200 according to the present invention in a housing 282, and an image can be displayed on a screen 283. FIG. 12A shows an application example to a television. Television 300 comprises the electro-optic device 200 according to the present invention. For a monitor device used in a personal computer or the like, the electro-optic device according to the present invention is similarly applicable.

FIG. 12B shows an application example to a roll-up type television. Roll-up type television 310 comprises the electro-optic device 200 according to the present invention.

Furthermore, the electro-optic device according to the present invention is not limited to the above-mentioned examples, but is applicable to any electronic equipment. For example, in addition to these examples, the electro-optic device can also be used for devices such as fax device with a display function, viewfinder of digital camera, portable television, electronic data book, electric bulletin board, and commercial display.

The present invention is not limited to the contents of the above-mentioned illustrative embodiments, but various modifications can be made within the scope of the gist of the present invention. For example, although in the respective illustrative embodiments described above, the organic EL display device is described as one example of the electric device, the application scope of the present invention is not so limited and can be applied to other various electric devices.

1. A manufacturing method of an electric device comprising the steps of:
forming a peeling layer on a first substrate;
forming a transferred layer that includes an electric element, on the peeling layer;
forming on the transferred layer a barrier layer;
bonding a second substrate to the transferred layer formation surface side of the first substrate via an adhesive layer; and
transferring energy to the peeling layer through the first substrate to cause peeling in the peeling layer and separation of the first substrate from the second substrate.

2. The manufacturing method of an electric device according to claim 1, wherein the electric element includes an organic EL element.

3. The manufacturing method of an electric device according to claim 1, further comprising:
forming a protective layer interposed between the peeling layer and the transferred layer, prior forming the transferred layer

4. A manufacturing method of an electric device comprising the steps of:
forming a first peeling layer on a first substrate;
forming on the first peeling layer a barrier layer;
forming a transferred layer that includes an electric element, on the barrier layer;
preparing a temporary transferring substrate for temporarily supporting the barrier layer and the transferred layer, and forming a second peeling layer on one surface of the temporary transferring substrate;
interposing an interim adhesive layer between the transferred layer side of the first substrate and the second peeling layer side of the temporary transferring substrate, and bonding the first substrate and the temporary transferring substrate;
transferring energy to the first peeling layer through the first substrate to cause peeling in the first peeling layer, and separation the first substrate from the temporary transferring substrate;
bonding a second substrate to the barrier layer formed on the transferred layer via an adhesive layer; and
transferring energy to the second peeling layer through the temporary transferring substrate to cause peeling in the second peeling layer, and separating the temporary transferring substrate from the second substrate.

5. The manufacturing method of an electric device according to claim 4, wherein said interim adhesive layer is a water-soluble adhesive.

6. The manufacturing method of an electric device according to claim 4, further comprising:
removing the interim adhesive layer after the transferring energy step.

7. The manufacturing method of an electric device according to claim 6, further comprising:
forming a protective layer on the transferred layer after the removing the adhesive layer step.

8. The manufacturing method of an electric device according to claim 4, further comprising:
forming a protective layer on the transferred layer after forming the transferred layer.

9. A manufacturing method of an electric device comprising the steps of:
forming a peeling layer on a first substrate;
forming a barrier layer on the peeling layer;
forming on the barrier layer a transferred layer that includes an electric element;
preparing a temporary transferring substrate for temporarily supporting the barrier layer and the transferred layer, and interposing an interim adhesive layer between one surface of the temporary transferring substrate and the transferred layer formation surface side of the first substrate, and bonding the first substrate and the temporary transferring substrate;
transferring energy to the peeling layer through the first substrate to cause peeling in the peeling layer, and separating the first substrate from the temporary transferring substrate;
bonding a second substrate to the barrier layer formed on the transferred layer via an adhesive layer; and
removing the interim adhesive layer, and separating the temporary transferring substrate from the second substrate.

10. The manufacturing method according to claim 9, wherein interim adhesive layer is water soluble.

11. A manufacturing method of an electric device comprising the steps of:
forming a peeling layer on a first substrate;
forming a barrier layer on the peeling layer;
forming a transferred layer on the barrier layer that includes at least a partially completed electric element;
preparing a second substrate for supporting the barrier layer and the transferred layer, and interposing a first adhesive layer between one surface of the second substrate and the layer side of the first substrate, and bonding the first substrate and the second substrate;
transferring energy to the peeling layer through the first substrate to cause peeling in the peeling layer and separation of the first substrate from the second substrate;
bonding a second substrate to the barrier layer formed on the transferred layer via a second adhesive layer; and
removing the first adhesive layer causing separation the second substrate from the second substrate.

12. The manufacturing method according to claim 11, further comprising:
completing said electric element.

13. The manufacturing method according to claim 11, wherein said barrier layer formation step includes completing said electric element prior to interposing said first adhesive layer.

14. An electric device, comprising:
a substrate;
an adhesive layer arranged on the substrate;
a barrier layer arranged on the adhesive layer; and
a device layer including an electric element and arranged on the barrier layer.

15. The electric device according to claim 14, further comprising:
a protective layer arranged on said device layer.

16. The electric device according to claim 15, wherein said electric element emits light through said protective layer.

17. The electric device according to claim 16, wherein said electric element emits light through said substrate.

18. Electronic equipment including the electric device manufactured by the manufacturing method according to claim 1.

19. Electronic equipment including the electric device manufactured by the manufacturing method according to claim 4.

20. Electronic equipment including the electric device manufactured by the manufacturing method according to claim 9.

21. Electronic equipment including the electric device manufactured by the manufacturing method according to claim 11.
